(19) United States
(12) Patent Application Publication
(10) Pub. No.: US 2020/0199750 A1
(43) Pub. Date: Jun. 25, 2020

(54) FILM FORMING APPARATUS AND FILM FORMING METHOD

(71) Applicant: Fuji Xerox Co., Ltd., Tokyo (JP)

(72) Inventor: Takeshi IWANAGA, Kanagawa (JP)

(73) Assignee: Fuji Xerox Co., Ltd., Tokyo (JP)

(21) Appl. No.: 16/379,802

(22) Filed: Apr. 10, 2019

(30) Foreign Application Priority Data
Dec. 21, 2018 (JP) 2018-240149

(51) Int. Cl. C23C 16/455; H01L 21/687; H01J 37/32; C23C 16/44; C23C 16/458

(52) U.S. Cl. CPC C23C 16/45557; H01L 21/68735; H01J 37/32651; H01J 2237/3321; C23C 16/4412; C23C 16/4585; H01J 37/32834

(57) ABSTRACT

A film forming apparatus includes a reaction vessel that has a film forming target member disposed therein and deposits a film having an element contained in a film forming gas as a constituent element on the film forming target member, utilizing excitation and decomposition of the film forming gas supplied thereto and that has a reaction active region where the film forming gas is capable of being excited and decomposed, and a reaction inactive region that is a region continuous with the reaction active region; a film forming gas supply device that supplies the film forming gas to the reaction inactive region within the reaction vessel; an excitation device that excites and decomposes the film forming gas in the reaction vessel; a holding device that has a holding member which holds the film forming target member, and a drive unit which drives the holding member between the reaction inactive region and the reaction active region and repeatedly moves the film forming target member and which supplies the film forming gas from the reaction inactive region to the reaction active region together with the movement of the film forming target member; and an exhaust member that is provided within the reaction vessel to exhaust a gas in the reaction vessel and that exhausts the gas in the reaction vessel that has passed through or over at least one of an interior or a side face of the film forming target member held by the holding member.

### CROSS-REFERENCE TO RELATED APPLICATIONS

This application is based on and claims priority under 35 USC 119 from Japanese Patent Application No. 2018-240149 filed Dec. 21, 2018.

### BACKGROUND

### (i) Technical Field

The present invention relates to a film forming apparatus and a film forming method.

### (ii) Related Art

In the related art, there are known a film forming apparatus and a film forming method that deposits a film having an element contained in a film forming gas as a constituent element on a film forming target member, utilizing excitation and decomposition of the film forming gas supplied thereinto.

As an example thereof, there is a plasma-enhanced chemical vapor deposition (plasma CVD). In the plasma CVD, since excitation and decomposition of the film forming gas is performed by cold plasma, an inorganic film can be formed at a low temperature. This makes it possible to form the inorganic film even in a case where the film forming target member is a member that cannot withstand a high temperature of 300° like a resin member.

For example, JP5055845B discloses “a thin film forming apparatus that deposits a film having an element contained in a raw material gas as a constituent element on a thin film forming target member, utilizing excitation and decomposition of the raw material gas supplied into a reaction vessel, and a thin film forming method. The thin film forming apparatus includes excitation means for exciting and decomposing the raw material gas; raw material gas supply means for supply the raw material gas to a reaction inactive region other than a reaction active region where the raw material gas is capable of being excited and decomposed by the excitation means within the reaction vessel and for supplying the raw material gas in a direction other than the reaction active region; and drive means that repeatedly moves the thin film forming target member between the reaction inactive region and the reaction active region. The reaction active region and the reaction inactive region are continuous regions. The reaction vessel is configured to include a shielding member that shields at least a portion of a boundary between the reaction active region and the reaction inactive region. The raw material gas supplied by the raw material gas supply means is supplied via the reaction inactive region to the reaction active region”.

Additionally, JP2761431B discloses “a film forming apparatus and a film forming method. The film forming apparatus includes a vacuum chamber in which a base material with a complicated three-dimensional shape is installed; a plurality of film forming gas supply nozzles that are disposed within this chamber to supply a film forming gas to the periphery of the base material from a plurality of directions; a plurality of exhaust ports that face the plurality of nozzles and open to a chamber wall part; means for interlocking supply of the film forming gas from the nozzles with exhaust from the exhaust ports that face the nozzles during the supply of the film forming gas; and means for generating plasma within the chamber”.

### SUMMARY

However, in the related-art film forming apparatus, the exhaust ports of the exhaust pipe that exhausts the gas in the reaction vessel are provided in an outer wall of the reaction vessel.

For that reason, a substantially uniform film is formed on the surface of the film forming target member capable of facing the reaction active region side. However, the film forming gas does not easily reach an interior (for example, wall faces of pores of a porous body, an inner peripheral face of a tubular member, wall faces of through-holes of a member having the through-holes, or the like) or a side face (a face that intersects the surface of the film forming target member capable of facing the reaction active region side) of the film forming target member, or the same film forming gas stagnates even in a case where the film forming gas reaches. Therefore, the film is not formed or the substantially uniform film is not easily formed.

Aspects of non-limiting embodiments of the present disclosure relate to a film forming apparatus, which realizes formation of a substantially uniform film on at least one of an interior or a side face of a film forming target member, compared to a film forming apparatus in which exhaust ports of an exhaust pipe that exhausts gas in a reaction vessel are provided in an outer wall of the reaction vessel.

Aspects of certain non-limiting embodiments of the present disclosure overcome the above disadvantages and/or other disadvantages not described above. However, aspects of the non-limiting embodiments are not required to overcome the disadvantages described above, and aspects of the non-limiting embodiments of the present disclosure may not overcome any of the disadvantages described above.

According to an aspect of the present disclosure, there is provided a film forming apparatus including a reaction vessel that has a film forming target member disposed therein and deposits a film having an element contained in a film forming gas as a constituent element on the film forming target member, utilizing excitation and decomposition of the film forming gas supplied thereto and that has a reaction active region where the film forming gas is capable of being excited and decomposed, and a reaction inactive region that is a region continuous with the reaction active region; a film forming gas supply device that supplies the film forming gas to the reaction inactive region within the reaction vessel; an excitation device that excites and decomposes the film forming gas in the reaction vessel; a holding device that has a holding member which holds the film forming target member, and a drive unit which drives the holding member between the reaction inactive region and the reaction active region and repeatedly moves the film forming target member and which supplies the film forming gas from the reaction inactive region to the reaction active region together with the movement of the film forming target member; and an exhaust member that is provided within the reaction vessel to exhaust a gas in the reaction vessel and that exhausts the gas in the reaction vessel that has passed through or over at least one of an interior or a side face of the film forming target member held by the holding member.

### BRIEF DESCRIPTION OF THE DRAWINGS

Exemplary embodiment (s) of the present invention will be described in detail based on the following figures, wherein:

FIG. 1 is a schematic plan cross-sectional view illustrating a film forming apparatus 101 related to Exemplary Embodiment A;

FIG. 2 is a schematic side cross-sectional view illustrating the film forming apparatus 101 related to Exemplary Embodiment A;

FIG. 3 is a schematic side cross-sectional view illustrating a film forming apparatus 102 related to Exemplary Embodiment B;

FIG. 4 is a schematic side cross-sectional view illustrating a film forming apparatus 103 related to Exemplary Embodiment C; and

FIG. 5 is a schematic plan cross-sectional view illustrating a film forming apparatus 104 related to Exemplary Embodiment D.

### DETAILED DESCRIPTION

Hereinafter, exemplary embodiments that are examples of the invention will be described.

A film forming apparatus related to a first exemplary embodiment includes a reaction vessel that has a film forming target member disposed therein and deposits a film having an element contained in a film forming gas as a constituent element on the film forming target member, utilizing excitation and decomposition of the film forming gas supplied thereto and that has a reaction active region where the film forming gas is capable of being excited and decomposed, and a reaction inactive region that is a region continuous with the reaction active region; a film forming gas supply device that supplies the film forming gas to the reaction inactive region within the reaction vessel; an excitation device that excites and decomposes the film forming gas in the reaction vessel; a holding device that has a holding member which holds the film forming target member, and a drive unit which drives the holding member between the reaction inactive region and the reaction active region and repeatedly moves the film forming target member and which supplies the film forming gas from the reaction inactive region to the reaction active region together with the movement of the film forming target member; and an exhaust member that is provided within the reaction vessel to exhaust a gas in the reaction vessel and that exhausts the gas in the reaction vessel that has passed through or over at least one of an interior or a side face of the film forming target member held by the holding member.

In the film forming apparatus related to a first exemplary embodiment, a film forming method (film forming method related to the first exemplary embodiment) is realized including a film forming gas supplying step of supplying a film forming gas to a reaction inactive region within a reaction vessel, using a film forming gas supply device, the reaction vessel having a film forming target member disposed therein and deposits a film having an element contained in the film forming gas as a constituent element on the film forming target member, utilizing excitation and decomposition of the film forming gas supplied thereto and that has a reaction active region where the film forming gas is capable of being excited and decomposed, and a reaction inactive region that is a region continuous with the reaction active region; an exciting step of exciting and decomposing the film forming gas in the reaction vessel; a moving step of driving a holding member between the reaction inactive region and the reaction active region in a state where the film forming target member is held by the holding member and repeatedly moves the film forming target member and supplying the film forming gas from the reaction inactive region to the reaction active region together with the movement of the film forming target member; and an exhausting step of exhausting a gas in the reaction vessel, using an exhaust member provided within the reaction vessel and exhausting the gas in the reaction vessel that has passed through or over at least one of an interior or a side face of the film forming target member held by the holding member.

In the film forming apparatus and the film forming method (hereinafter, the film forming apparatus and the film forming method related to the first exemplary embodiment may be collectively referred to as an apparatus related to the first exemplary embodiment) related to the first exemplary embodiment, formation of a substantially uniform film is realized on at least one of the interior or the side face of the film forming target member. The reasons are estimated as follows.

First, in the film forming apparatus related to a first exemplary embodiment, the film forming gas is supplied to the reaction inactive region by the film forming gas supply device in the reaction vessel having the reaction active region where the film forming gas is capable of being excited and decomposed, and the reaction inactive region, which is a region continuous with the reaction active region.

As the film forming gas is first supplied to the reaction inactive region instead of the reaction active region, uniformization of the density of the film forming gas is promoted due to diffusion, adsorption, and re-evaporation of the film forming gas.

Next, in a case where the film forming target member is repeatedly moved between the reaction inactive region and the reaction active region by the drive unit of the holding device, the film forming gas is repeatedly supplied from the reaction inactive region to the reaction active region with the movement of the film forming target member held by the holding member. That is, the film forming gas reaches the reaction active region in a state where the density is made uniform in the reaction inactive region. For that reason, in the reaction active region, deposition of a reaction product of an excited and decomposed gas by the excitation and decomposition of the film forming gas occurs in a substantially uniform state on the surface of the film forming target member. Accordingly, it is suppressed that a film with nonuniform film thickness and film quality is formed on the film forming target member.

On the other hand, in the related-art film forming apparatus, the exhaust ports of the exhaust member that exhausts the gas in the reaction vessel are provided in the outer wall of the reaction vessel.

For that reason, a substantially uniform film is formed on the surface of the film forming target member capable of facing the reaction active region side. However, the film forming gas does not easily reach an interior (for example, wall faces of pores of a porous body, an inner peripheral face of a tubular member, wall faces of through-holes of a member having the through-holes, or the like) or a side face (a face that intersects the surface of the film forming target member capable of facing the reaction active region side) of the film forming target member, or the film forming gas stagnates even in a case where the film forming gas reaches. Therefore, the film is not formed or the substantially uniform film is not easily formed.

This is because, in a case where the film forming gas does not reach or the film forming gas stagnates even in a case where the film forming gas reaches, the decomposition and excitation of the film forming gas and the reaction of the excited and decomposed gas of the film forming gas does not proceed easily or the deposition of the reaction product does not occur or does not occur easily.

In contrast, in the film forming apparatus related to the first exemplary embodiment, the gas in the reaction vessel that has passed through at least one of the interior of the film forming target member held by the holding member or the holding member holding the film forming target member is exhausted in the reaction active region by the exhaust member.

Here, the gas in the reaction vessel passing through the interior of the film forming target member held by the holding member means that a space surrounded by the wall face is provided inside the film forming target member and the gas in the reaction vessel flows from a surface side of the film forming target member capable of facing the reaction active region side through the space to a rear face side thereof. In addition, for example, the space surrounded by the wall face inside the film forming target member is equivalent to the pores in a case where the film forming target member is the porous body, is equivalent to a region surrounded by the inner peripheral face of the tubular member in a case where the film forming target member is the tubular member, and is equivalent to through-holes in a case where the film forming target member is the member having the through-holes.

Additionally, the gas in the reaction vessel passing over the side face of the film forming target member held by the holding member means that the gas in the reaction vessel flows from the surface side of the film forming target member capable of facing the reaction active region side to the rear face side thereof while being in contact with the side face of the film forming target member.

That is, in the film forming apparatus related to the first exemplary embodiment, a gas exhaust port of the exhaust member is installed at a position where the gas in the reaction vessel flows through or over at least one of the interior or the side face of the film forming target member and is then exhausted.

Accordingly, the film forming gas supplied into the reaction vessel flows to and reaches the interior (for example, the wall faces of the pores of the porous body, the inner peripheral face of the tubular member, the wall faces of the through-holes of the member having the through-holes, or the like) or the side face (the face that intersects the surface of the film forming target member capable of facing the reaction active region side) of the film forming target member. Then, in the reaction inactive region, the film forming gas is adsorbed on the interior (for example, the wall faces of the pores of the porous body, the inner peripheral face of the tubular member, the wall faces of the through-holes of the member having the through-holes, or the like) or the side face (the face that intersects the surface of the film forming target member capable of facing the reaction active region side) of the film forming target member. In that state, in a case where the film forming target member (that is, the adsorbed film forming gas) reaches the reaction active region, the film forming gas is decomposed and excited, and the deposition of the reaction product of the excited and decomposed gas occurs. Then, in a case where the film forming target member is repeatedly moved between the reaction inactive region and the reaction active region, the film forming gas flows through or over the interior or the side face of the film forming target member. Thus, this action occurs repeatedly. For that reason, the deposition of the reaction product of the excited and decomposed gas occurs in a substantially uniform state in at least one of the interior or the side face of the film forming target member.

From the above, in the film forming apparatus and the film forming method related to a first exemplary embodiment, it is estimated that the formation of the substantially uniform film is also realized on at least one of the interior or the side face of the film forming target member.

Meanwhile, a film forming apparatus related to a second exemplary embodiment is a film forming apparatus including a reaction vessel that has a film forming target member disposed therein and deposits a film having an element contained in a film forming gas as a constituent element on the film forming target member, utilizing excitation and decomposition of the film forming gas supplied thereto; a film forming gas supply device that supplies the film forming gas to the reaction vessel; an excitation device that excites and decomposes the film forming gas in the reaction vessel; a holding member that is provided within the reaction vessel and holds the film forming target member; and an exhaust member that is provided within the reaction vessel to exhaust a gas in the reaction vessel and that exhausts the gas in the reaction vessel that has passed through or over at least one of an interior or a side face of the film forming target member held by the holding member.

In the film forming apparatus related to the second exemplary embodiment, a film forming method (film forming method related to the second exemplary embodiment) is realized including a film forming gas supplying step of supplying a film forming gas to a reaction vessel, using a film forming gas supply device, the reaction vessel having a film forming target member disposed therein and deposits a film having an element contained in the film forming gas as a constituent element on the film forming target member, utilizing excitation and decomposition of the film forming gas supplied thereto; an exciting step of exciting and decomposing the film forming gas in the reaction vessel; and an exhausting step of exhausting a gas in the reaction vessel, using an exhaust member provided within the reaction vessel and exhausting the gas in the reaction vessel that has passed through or over at least one of an interior or a side face of the film forming target member held by a holding member.

In the film forming apparatus and the film forming method (hereinafter, the film forming apparatus and the film forming method related to the second exemplary embodiment may be collectively referred to as an apparatus related to the second exemplary embodiment) related to the second exemplary embodiment, formation of a substantially uniform film is realized on at least one of the interior or the side face of the film forming target member.

The reason is that it is estimated that the film forming gas (or the excited and decomposed gas) flows to and reaches the interior (for example, the wall faces of the pores of the porous body, the inner peripheral face of the tubular member, the wall faces of the through-holes of the member having the through-holes, or the like) or the side face (the face that intersects the surface of the film forming target member capable of facing the reaction active region side) of the film forming target member due to the exhaust member for the same reason as the film forming apparatus related to the first exemplary embodiment.

Hereinafter, a film forming apparatus and a film forming method related to exemplary embodiments will be described, referring to the drawings.

In addition, members having substantially the same functions will be given the same reference numerals throughout the drawings, and duplicate descriptions may be appropriately omitted.

### Exemplary Embodiment A

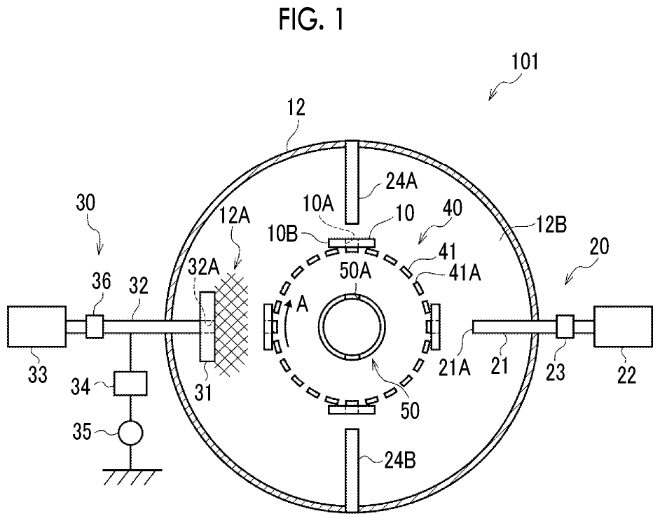

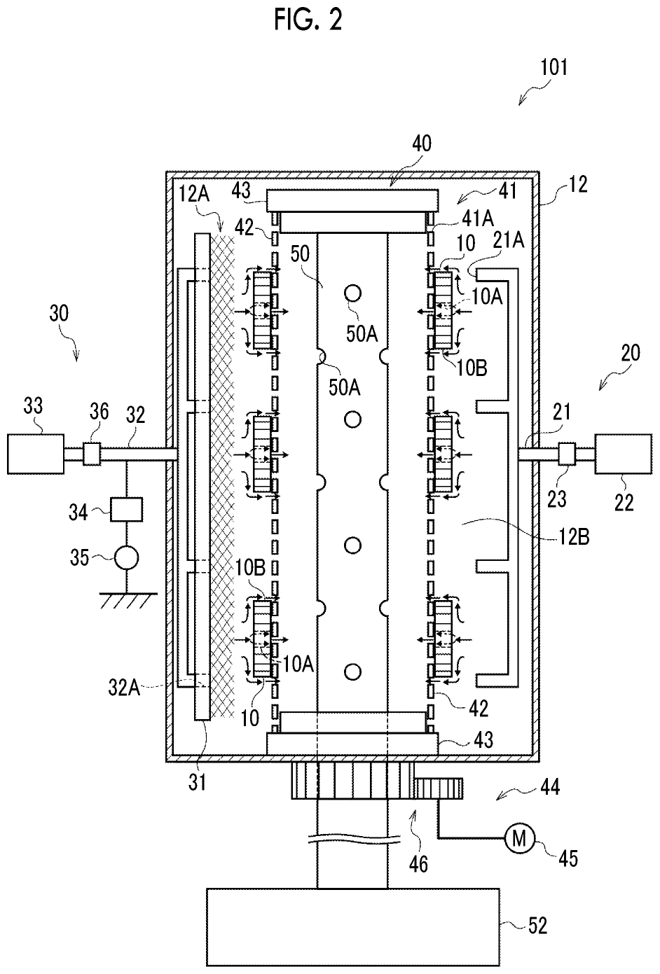

FIG. 1 is a schematic plan cross-sectional view illustrating a film forming apparatus 101 related to Exemplary Embodiment A. FIG. 2 is a schematic side cross-sectional view illustrating the film forming apparatus 101 related to Exemplary Embodiment A.

As illustrated in FIGS. 1 and 2, the film forming apparatus 101 related to Exemplary Embodiment A is an apparatus that forms a film having an element contained in a film forming gas as a constituent element on a film forming target member 10, utilizing excitation and decomposition of the film forming gas.

Specifically, as illustrated in FIGS. 1 and 2, for example, the film forming apparatus 101 includes a reaction vessel 12; a film forming gas supply device 20 that supplies the film forming gas into the reaction vessel 12; an excitation device 30 that excites and decomposes the film forming gas in the reaction vessel 12; a holding device 40 that holds the film forming target member 10, and an exhaust pipe 50 which is an example of an exhaust member exhausts the gas in the reaction vessel 12.

The film forming apparatus 101 also includes an evacuation device 52 for evacuating the gas in the reaction vessel 12 through the exhaust pipe 50.

A film to be formed by the film forming apparatus 101 is a film that is obtained by growing on a wall face of the film forming target member 10, and specifically, indicates a film of about 0.1 nm to 100 μm.

As the film, a nitride film, an oxide film, a silicon-based film, a carbon-based film, a simple substance film or an alloy film of metals, or the like is exemplified.

The crystal structure of the film may be crystalline, such as mono-crystalline and polycrystalline, or may be amorphous. Additionally, a microcrystal structure in which crystal grains having a grain size of 5 nm to 100 μm are dispersed in an amorphous material may also be used.

As the film forming target member 10, a member, which forms a film on at least one of an interior (for example, wall faces of pores of a porous body, an inner peripheral face of a tubular member, wall faces of through-holes of a member having the through-holes, or the like) or a side face (a face that intersects the surface of the film forming target member capable of facing the reaction active region 12A side) in addition to a surface of the film forming target member 10 capable of being facing a reaction active region 12A side, becomes a target.

Specifically, the film forming target member 10 that forms a film inside includes, for example, a member having an opening part through which the gas (excited and decomposed gas or the like of the film forming gas or a film non-forming gas) within the reaction vessel 12 passes. As the member having an opening part, a porous body (a filter, a separator of a secondary battery, or the like), a tubular member (a pipe, a belt, or the like), a member having through-hole in a thickness direction, or the like is exemplified.

Additionally, a gear or the like is exemplified as the film forming target member 10 that forms a film on a side face.

In addition, as the film forming target member 10, a disk-shaped member (for example, a gear) having an opening part 10A through which the gas (the excited and decomposed gas or the like of the film forming gas or the film non-forming gas) within the reaction vessel 12 passes to a central part illustrated is in FIGS. 1 and 2. The film forming apparatus 101 forms a film on a wall face (that is, an inner peripheral face) constituting the opening part 10A, and a side face 10B.

The film forming target member 10 is disposed inside the reaction vessel 12. Specifically, the film forming target member 10 is disposed inside the reaction vessel 12 in a state where the film forming target member 10 is held by (a holding member 41 of) the holding device 40.

A reaction active region 12A where the film forming gas is capable of being excited and decomposed, and a reaction inactive region 12B, which is a region continuous with the reaction active region 12A, are provided inside the reaction vessel 12. Two shielding members 24A and 24B that shield at least a portion between the reaction active region 12A and the reaction inactive region 12B are disposed inside the reaction vessel.

Here, the reaction active region 12A means a region where the film forming gas is excited and decomposed when the film forming gas reaches the region. In addition, in a case where the film non-forming gas, the reaction active region 12A also means a region where the film non-forming gas is excited and decomposed when the film non-forming gas reaches the region. Specifically, in the exemplary embodiment, the reaction active region 12A means a region where the film forming gas is exposed to the excited and decomposed gas (that is, film non-forming plasma) of the film non-forming gas and is excited and decomposed, in addition to the region where the film non-forming gas is excited and decomposed.

On the other hand, the reaction inactive region 12B means the region that is continuous with the reaction active region 12A, and a region where the film forming gas is not excited and decomposed even in a case where the film forming gas is present.

The holding device 40 has a holding member 41 that holds the film forming target member 10, and a drive unit 44 that drives the holding member 41 and repeatedly moves the film forming target member 10, between the reaction inactive region 12B and the reaction active region 12A, and that supplies the film forming gas from the reaction inactive region 12B to the reaction active region with the movement of the film forming target member.

The holding member 41 is made of, for example, a tubular member. The tubular member has, for example, an opening part 41A through which the gas (the excited and decomposed gas or the like of the film forming gas or the film non-forming gas) within the reaction vessel 12 permeates. Specifically, the holding member 41 has, for example, a tubular part 42 having the opening part 41A through which the gas (the excited and decomposed gas or the like of the film forming gas or the film non-forming gas) within the reaction vessel 12 permeates, and a support part 43 that supports both axial ends of the tubular part 42.

The holding member 41 (the tubular part 42 thereof) is provided, for example, to be interposed between a film forming gas supply port 21A of the film forming gas supply device 20 and the exhaust pipe 50. The holding member 41 is provided, for example, to be interposed between the reaction active region 12A and the exhaust pipe 50.

Specifically, the exhaust pipe 50 is provided inside the holding member 41 made of the tubular member. On the other hand, the shielding member 24A, a film forming gas supply pipe 21 of the film forming gas supply device 20, the shielding member 24B, and a discharge electrode 31 of the excitation device 30 are provided in this order in a rotational direction (a direction of arrow A) of the holding member around the exterior of the holding member 41. The reaction active region 12A and the reaction inactive region 12B, which are shielded by the two shielding members 24A and 24B, are present around the exterior of the holding member 41.

The tubular part 42 of the holding member 41 holds the film forming target member 10 on an outer peripheral face thereof. Specifically, the film forming target member 10 is held by, for example, a double-sided tape, a fastener, or the like on the outer peripheral face of the tubular part 42.

As the tubular part 42, for example, a net-like body in which metal wires are disposed in a crossed manner, a net-like body in which metal strips are disposed in a crossed manner, a net-like body in which a metal plate is subjected to meshing, or the like are exemplified.

The tubular part 42 may be cylindrical or polygonal cylindrical. In addition, FIGS. 1 and 2 illustrate a cylindrical part as the tubular part 42.

In addition, the tubular part 42 of the holding member 41 may be a member having flexibility even in a case where the tubular part 42 is a member having a self-supporting property (for example, stiffness). In a case a where the tubular part 42 of the holding member 41 is the member having flexibility, the support part 43 of the holding member 41 may be the support part 43 that supports the tubular part 42 while being in contact with the inner peripheral face of the tubular part 42 and applying tension to the tubular part 42.

Additionally, the holding member 41 may be an ended belt, a plate-shaped member, or the like.

The drive unit 44 of the holding device 40 has, for example, a motor 45 that drives the holding member 41, and a driving transmission part 46 (gear or the like) that is coupled to one support part 43 of the holding member 41 and transmit a driving force of the motor 45 to the holding member 41.

Specifically, the drive unit 44, for example, transmits the rotational driving of the motor 45 to the holding member 41 by the driving transmission part 46 and rotationally drives the holding member 41 in the direction of arrow A. Accordingly, the film forming target member 10 is repeatedly moved between the reaction inactive region 12B and the reaction active region 12A.

In addition, the drive unit 44 of the holding device 40 may have an aspect in which forward rotational driving and reverse rotational driving of the holding member 41 are repeated, without being limited to an aspect in which the holding member 41 is rotationally driven in one direction.

Additionally, in a case where the holding member 41 is the ended belt, the plate-shaped member, or the like, the drive unit 44 may have an aspect in which the holding member 41 is reciprocally driven.

The film forming gas supply device 20 has the film forming gas supply pipe 21 and a film forming gas supply source 22.

The film forming gas supply pipe 21 is a pipe for supplying the film forming gas from the exterior of the reaction vessel 12 to the interior of the reaction vessel 12. The film forming gas supply pipe 21 communicates with the interior of the reaction vessel 12 via one or a plurality of film forming gas supply port 21A provided at one end of the film forming gas supply pipe 21. On the other hand, the other end of the film forming gas supply pipe 21 is connected to the film forming gas supply source 22 via an electromagnetic valve 23.

The film forming gas supply source 22 includes, for example, a vessel filled with the film forming gas, a mechanism, such as a constant temperature bath, which adjusts the temperature of the film forming gas, a mechanism that adjusts the pressure of a regulator or the like, and a mechanism, such as a mass flow controller, which adjusts the flow rate of the film forming gas (not illustrated). In a case where the film forming gas is a gas obtained by gasifying liquid or solid, the film forming gas is filled into the constant temperature bath kept at a targeted temperature, and is supplied into the reaction vessel 12 together with a carrier gas as necessary. In a case where the carrier gas is supplied, the carrier gas is adjusted to a targeted pressure and supplied.

The film forming gas supplied from the film forming gas supply source 22 to the film forming gas supply pipe 21 reaches the film forming gas supply port 21A through the film forming gas supply pipe 21 and is sprayed from the film forming gas supply port 21A to the interior of the reaction vessel 12.

The film forming gas supply port 21A is provided at the film forming gas supply pipe 21 in the reaction inactive region 12B within the reaction vessel 12.

The film forming gas supply port 21A may be provided in a region away from a boundary between the reaction active region 12A and the reaction inactive region 12B. In addition, for example, it is preferable that the “region away from a boundary between the reaction active region 12A and the reaction inactive region 12B” is a region where diffusion is performed in order to make the density of the film forming gas uniform in the reaction inactive region 12B, specifically, a region 20 mm or more away from the boundary between the reaction active region 12A and the reaction inactive region 12B.

By providing the film forming gas supply port 21A in the region away from the boundary between the reaction active region 12A and the reaction inactive region 12B, a situation in which the film forming gas is introduced into the reaction active region 12A due to nonuniform density and a film with nonuniform film thickness and film quality is formed is suppressed.

For example, it is preferable that a direction in which the film forming gas is sprayed from the film forming gas supply port 21A is a direction in which the film forming gas is sprayed toward the film forming target member 10 serving as a film forming target.

Specifically, for example, it is preferable that the direction in which the film forming gas is sprayed from the film forming gas supply port 21A is a direction in which the film forming gas is sprayed toward the outer peripheral face of the holding member 41 (the tubular part 42 thereof).

More specifically, for example, it is preferable that the direction in which the film forming gas is sprayed from the film forming gas supply port 21A is a direction in which the film forming gas flows in directions other than toward the reaction active region 12A in the reaction inactive region 12B.

In a case where the film forming gas flows in the directions other than toward the reaction active region 12A, the film forming gas moves through the interior of the reaction vessel 12 to easily reach the reaction active region 12A, in a state where the density is made uniform.

In addition, the “film forming gas” is a gas that may produce a reaction product in a simple substance or in reaction with the excited and decomposed gas of the excited and decomposed film non-forming gas, after being excited and decomposed. Specifically, the film forming gas is a gas that precipitates a reaction product having an element contained in the film forming gas as a constituent element after being excited and decomposed, or a gas that precipitates a reaction product having an element contained in the film forming gas and the film non-forming gas as a constituent element in reaction with an element constituting the excited and decomposed film non-forming gas after being excited and decomposed.

For example, in a case where a film of a nitride of a group 13 element or an oxide of the group 13 element is formed, a compound gas containing the group 13 element is adopted as the film forming gas.

Specifically, as the film forming gas, trimethyl gallium, trimethyl indium, trimethyl aluminum, triethyl gallium, triethyl indium, triethyl aluminum, t-butyl gallium, t-butyl indium, diborane, boron trifluoride, boron trichloride, boron tribromide, or the like is exemplified.

Additionally, in a case where a film of a zinc oxide is formed, dimethyl zinc, diethyl zinc, or the like is exemplified as the film forming gas.

In a case where a silicon-based film, such as a polycrystalline silicon film, an amorphous silicon film, a silicon nitride film, or a silicon oxide film, is formed, inorganic silane, such as SiH₄ or Si₂H₆; organic silane, such as tetraethoxysilane (TEOS), tetramethoxysilane (TMOS), octamethylcyclotetrasilane (OMCTS), tetramethylsilane, tetra-ethyl silane (TES), or mono-methyl silane; or halosilane, such as SiF₄, Si₂F₆, SiHF₃, SiH₂F₂, SiCl₄, Si₂Cl₆, SiHCl₃, SiH₂Cl₂, SiH₃Cl, or Si₂Cl₂F₂, is exemplified as the film forming gas.

Additionally, in a case where the carbon-based film, such as DLC (diamond-like carbon: α-C) is formed, hydrocarbon, such as methane, ethane, propane, or toluene, is exemplified as the film forming gas.

Additionally, in a case where a simple substance film of metals, such as an AL film, a Ga film, or an In film, or an alloy film of metals is formed, a compound containing Al, such as trimethyl aluminum or triethyl aluminum, a compound containing Ga, such as trimethyl gallium or triethyl gallium, a compound containing In, such as trimethyl indium, is exemplified as the film forming gas.

The excitation device 30 has the discharge electrode 31, the film non-forming gas supply pipe 32, and the film non-forming gas supply source 33.

The discharge electrode 31 is connected to a high-frequency power source 35 that supplies electric power to the discharge electrode 31 via a matching box 34. A DC power source or an AC power source is used for the high-frequency power source 35 as an electric power supply source.

Particularly, since the high-frequency power source 35 can excite gas efficiently, an AC high-frequency power source, a microwave power source, or the like can be used.

The discharge electrode 31 is provided such that a discharge face thereof faces an outer peripheral face of the holding member 41 of the holding device 40, and the discharge face is spaced apart from the holding member 41. However, the orientation of the discharge face of the discharge electrode 31 may be a direction in which at least a portion of produced plasma is in contact with the film forming target member 10 held by the holding member 41.

In addition, although a case where a discharge method based on the discharge electrode 31 is a capacitive type will be described, an induction type may be used.

As the discharge electrode 31, for example, a gas permeation type electrode having a hollow shape and having (hollow structure) a plurality of gas supply holes (not illustrated) for supplying the film non-forming gas to the discharge face is exemplified. In a case where a discharge electrode having no hollow structure and having no gas supply holes in the discharge face is used as the discharge electrode 31, the excitation device 30 has, for example, an aspect in which the film non-forming gas supply pipe 32 is disposed such that the film non-forming gas supplied from a separately provided the film non-forming gas supply port 32A pass through between the discharge electrode 31 and the holding members 41.

For example, it is preferable that the discharge electrode 31 is covered with an insulating member such that an electrode face other than a face facing the outer peripheral face of the holding member 41 has a gap that is about 3 mm or less so that discharge does not occur between the discharge electrode 31 and the reaction vessel 12.

The film non-forming gas supply pipe 32 is a pipe for supplying the film non-forming gas into the reaction vessel 12. One end of the film non-forming gas supply pipe 32 communicates with the interior of the reaction vessel 12 via one or a plurality of the film non-forming gas supply ports 32A that are previously open in a direction that intersects the discharge face of the discharge electrode 31. The other end of the film non-forming gas supply pipe 32 is connected to the film non-forming gas supply source 33 via an electromagnetic valve 36.

The film non-forming gas supply source 33 includes, for example, a vessel filled with the film non-forming gas, a mechanism that adjusts the pressure of a regulator or the like, and a mechanism that adjusts the flow rate of the film forming gas, such as a mass flow controller. In a case where a plurality of film non-forming gases are used, these gases may be joined together and supplied.

The film non-forming gas is supplied into the reaction vessel 12 from the film non-forming gas supply port 32A via the film non-forming gas supply pipe 32 from the film non-forming gas supply source 33.

In addition, the “film non-forming gas” is a gas that does not produce a reaction product and does not form a film in a simple substance after being excited (that is, a gas that does not have a film forming property). For this reason, even in a case where the film non-forming gas is supplied to the reaction active region 12A in a simple substance, a reaction product is not produced in the film non-forming gas simple substance.

Gases such as N₂, H₂, NH₃, N₂H₄, O₂, O₃, NO, N₂O, He, Ar, Ne, Kr, and Xe, or such mixed gases thereof are exemplified in examples of the film non-forming gas.

Particularly, in a case where a nitride is produced as a reaction product of the excited and decomposed gas obtained by the film forming gas being excited and decomposed (in a case where the nitride film is formed), for example, a gas containing N as the film non-forming gas is used.

Additionally, in a case where an oxide is produced as a reaction product of the excited and decomposed gas obtained by the film forming gas being excited and decomposed (in a case where the oxide film is formed), for example, a gas containing O (oxygen) as the film non-forming gas is used.

The exhaust pipe 50 is a pipe for exhausting the gas in the reaction vessel 12 via a plurality of discharge ports 50A.

One end of the exhaust pipe 50 is closed, for example. On the other hand, the other end of the exhaust pipe 50 is connected to the evacuation device 52 for evacuating the gas in the reaction vessel 12.

The exhaust pipe 50 is provided, for example, to face the film forming gas supply port 21A of the film forming gas supply device 20 via the film forming target member 10 to be held by the holding member 41. Additionally, the exhaust pipe 50 is provided, for example, to face the reaction active region 12A within the reaction vessel 12 via the film forming target member 10 to be held by the holding member 41.

Specifically, the exhaust pipe 50 is provided, for example, on an inner peripheral face side of the tubular member (the tubular part 42 thereof) serving as the holding member 41, and exhausts the gas (the film forming gas, the film non-forming gas, the excited and decomposed gases thereof, or the like) supplied into the reaction vessel 12.

By providing the exhaust pipe 50 inside the inner peripheral face of the holding member 41, the exhaust pipe 50 exhausts the excited and decomposed gases (that is, the film non-forming plasma) of the film forming gas and the film non-forming gas that have passed over the wall face of the opening part 10A and the side face 10B in the film forming target member 10 held by the holding member 41.

Specifically, for example, in the reaction inactive region 12B, the film forming gas, which has passed over the wall face of the opening part 10A and the side face 10B in the film forming target member 10 held by the holding member 41, is exhausted. In the reaction active region 12A, the excited and decomposed gases (that is, the film non-forming plasma) of the film non-forming gas, which have passed over the wall face of the opening part 10A and the side face 10B in the film forming target member 10 held by the holding member 41, are exhausted.

In addition, the exhaust member is not limited in configuration as long as the exhaust pipe 50 has an aspect in which the exhaust pipe 50 performs exhaustion so as to cause a flow in which the gas (the excited and decomposed gases or the like (at least the film forming gas or the like in the case of an aspect in which only the film forming gas is supplied into the reaction vessel 12) of the film forming gas and the film non-forming gas) within the reaction vessel 12 passes over at least one of the wall face of the opening part 10A or the side face 10B of the film forming target member 10 held by the holding member 41.

The evacuation device 52 is a device that reduces the pressure inside the reaction vessel 12 to a targeted pressure. The evacuation device 52 has, for example, one or a plurality of pumps, and an exhaust speed adjusting mechanism, such as a conductance valve, as necessary.

In addition, 1 Pa to 200 Pa are exemplified as the pressure of the reaction vessel 12 inside at the time of film formation determined from gas supply amount and exhaust speed. However, the pressures inside reaction vessel 12 at the time of the film formation may be the pressure to be generated by the plasma inside the pressure of reaction vessel 12, and also depends on the type of gas and the type of power source.

The shielding members 24A and 24B are members that are provided within the reaction vessel 12 to shield at least a portion between the reaction active region 12A and the reaction inactive region 12B. The shielding members 24A and 24B are constituted of, for example, plate-shaped members. One end of each of the shielding members 24A and 24B is fixed to an inner wall of the reaction vessel 12, and the other end of each of the shielding members 24A and 24B faces the outer peripheral face of the holding member 41 (the tubular part 42 thereof) so as to be spaced apart therefrom.

When the film forming gas is supplied to the reaction inactive region 12B, the shielding members 24A and 24B may be provided to shield the excited and decomposed gas (that the film non-forming plasma) of the film non-forming gas of the reaction active region 12A to such an extent that a targeted reaction product is not produced due to the excitation and decomposition.

The minimum spacing between the shielding members 24A and 24B and the outer peripheral face of the holding member 41 (the tubular part 42 thereof) is set to, for example, a spacing such that a portion of a region between the reaction inactive region 12B and the reaction active region 12A is covered and the film formation of the film forming target member 10 held by the holding member 41 is not hindered.

Specifically, for example, in a case where the shielding members 24A and 24B and the film forming target member 10 face each other, the shortest distance between the shielding members 24A and 24B and the film forming target member 10 is, for example, preferably 10 mm or more, and more preferably 2 mm or more.

In addition, for example, it is preferable to adjust the distance between the shielding members 24A and 24B and the film forming target member 10. The distance may be adjusted, for example, by adopting a configuration in which the shielding members 24A and 24B are detachably provided with respect to the reaction vessel 12 and attaching the shielding members 24A and 24B having a size according to the size of the film forming target member 10 and the film thickness of a targeted film.

In addition, the shielding members 24A and 24B and the holding member 41 (the tubular part 42 thereof) or the film forming target member 10 may be in contact with each other. However, for example, it is preferable that the shielding members 24A and 24B and the holding member 41 (the tubular part 42 thereof) or the film forming target member 10 are in contact with each other with a pushing force such that does not cause friction therebetween. This is because the shielding members 24A and 24B suppress occurrence of damage to the film forming target member 10 itself, occurrence of damage to a film formed on the film forming target member 10, and shaving of the film formed on the film forming target member 10.

The materials of the shielding members 24A and 24B are not particularly limited as long as the materials have mechanical strength, may be conductive members, or may be insulating members.

However, in a case where the shielding members 24A and 24B are provided so as to come into contact with the holding member 41 (the tubular part 42 thereof) or the film forming target member 10, materials having a hardness lower than the film forming target member 10 and a film formed in the film forming target member 10 may be used from viewpoints of suppressing damage to the film forming target member 10 itself, damage to the film, and peeling of the film.

In addition, the shielding members 24A and 24B are members provided as necessary. However, size reduction of the device is realized by shielding the reaction inactive region 12B with the shielding members 24A and 24B from the reaction active region 12A. Therefore, for example, it is preferable to provide the shielding members 24A and 24B.

Next, the film forming method based on the film forming apparatus 101 will be described.

First, in the film forming apparatus 101, the film forming target member 10 is held by the outer peripheral face of the holding member 41 (the tubular part 42 thereof).

Next, the evacuation device 52 is driven to reduce the pressure inside the reaction vessel 12 to the targeted pressure. After the pressure inside the reaction vessel 12 is reduced, in the holding device 40, the holding member 41 is rotationally driven by the drive unit 44.

Next, in the excitation device 30, high-frequency power is supplied from the high-frequency power source 35 via the matching box 34 to the discharge electrode 31. The electromagnetic valve 36 is opened to supply the film non-forming gas to a region (that is, the reaction active region 12A) within the reaction vessel 12 where the discharge face of the discharge electrode 31 and the outer peripheral face of the holding member 41 face each other through the film non-forming gas supply pipe 32 and the film non-forming gas supply port 32A from the film non-forming gas supply source 33. Then, the excited and decomposed gas (that is, the film non-forming plasma) of the film non-forming gas is produced due to discharge from the discharge face of the discharge electrode 31.

On the other hand, the electromagnetic valve 23 is opened to supply the film forming gas from the film forming gas supply source 22 through the film forming gas supply port 21A of the film forming gas supply pipe 21 to the reaction inactive region 12B within the reaction vessel 12.

Then, in the reaction inactive region 12B, due to the exhaust pressure of the exhaust pipe 50, the film forming gas passes over the wall face of the opening part 10A and the side face 10B in the film forming target member 10 held by the holding member 41 and is exhausted from the exhaust pipe 50. At that time, the film forming gas is adsorbed on the wall face of the opening part 10A and the side face 10B as well as on the surface of the film forming target member 10 held by the holding member 41.

The film forming gas, which stays around the film forming target member 10, out of the film forming gas supplied from the film forming gas supply port 21A to the reaction inactive region 12B, and the film forming gas, which is adsorbed on the wall face of the opening part 10A and the side face 10B as well as on the surface of the film forming target member 10, moves to the reaction active region 12A with the movement of the film forming target member 10 resulting from the rotational driving of the holding member.

Then, in the reaction active region 12A, due to the exhaust pressure of the exhaust pipe 50, the produced excited and decomposed gas (that is, the film non-forming plasma) of the film non-forming gas passes over the wall face of the opening part 10A and the side face 10B in the film forming target member 10 held by the holding member 41 and is exhausted from the exhaust pipe 50. Then, the film forming gas, which is present around the film forming target member 10, and the film forming gas, which is adsorbed on the interior and the side face as well as on the surface of the film forming target member 10, are exposed to the excited and decomposed gas (that is, the film non-forming plasma) of the film non-forming gas. Accordingly, the film forming gas is excited and decomposed.

Then, the reaction product having the element contained in the film forming gas as the constituent element or the reaction product having the element contained in the film forming gas and the element contained in the film non-forming gas as the constituent element are produced. The produced reaction product deposits on the surface and on the wall face of the opening part 10A and the side face 10B in the film forming target member 10. As a result, a film having the element contained in the film forming gas as the constituent element or a film having the element contained in the film forming gas and the element contained in the film non-forming gas as the constituent element are formed on the surface of the film forming target member 10 and on the wall face of the opening part 10A and the side face 10B.

As the rotation of the holding member 41 is continued, the film forming target member 10 repeated move between the reaction active region 12A and the reaction inactive regions 12B within the reaction vessel 12. As a result, the reaction product having the element contained in the film forming gas or the element contained in the film non-forming gas and the element contained in the film forming gas as the constituent element gradually deposits on the opening part 10A and the side face 10B of the film forming target member 10, and a film with larger layer thickness is formed.

Then, the film forming gas, the film non-forming gas, and the excited and decomposed gases thereof, which have passed through the holding member 41 (the tubular part 42 thereof) as well as over the opening part 10A and the side face 10B of the film forming target member 10 and has not contributed to a reaction, is exhausted by the exhaust pipe 50.

Here, an example in a case where a gallium oxide (α-Ga₂O₃) film is formed as a film will be specifically described.

In a case where the gallium oxide (GaO) film is formed as a film, for example, a mixed gas of hydrogen and oxygen is supplied to the region (that is, the reaction active region 12A) within the reaction vessel 12 where the discharge face of the discharge electrode 31 and the outer peripheral face of the holding member 41 face each other, as the film non-forming gas. Then, an excited and decomposed gas (that is, hydrogen plasma) of hydrogen and an excited and decomposed gas (that is, oxygen plasma) of oxygen is produced due to the discharge from the discharge face of the discharge electrode 31.

On the other hand, trimethyl gallium is supplied to the reaction inactive region 12B within the reaction vessel 12 as the film forming gas.

Then, in the reaction inactive region 12B, due to the exhaust pressure of the exhaust pipe 50, the trimethyl gallium passes over the wall face of the opening part 10A and the side face 10B in the film forming target member 10 held by the holding member 41 and is exhausted from the exhaust pipe 50. At that time, the trimethyl gallium is adsorbed on the wall face of the opening part 10A and the side face 10B as well as on the surface of the film forming target member 10 held by the holding member 41.

The trimethyl gallium, which stays around the film forming target member 10, and the trimethyl gallium, which is adsorbed on the wall face of the opening part 10A and the side face 10B as well as on the surface of the film forming target member 10, moves to the reaction active region 12A with the movement of the film forming target member 10 resulting from the rotational driving of the holding member.

Then, in the reaction active region 12A, due to the exhaust pressure of the exhaust pipe 50, the produced excited and decomposed gas (that is, the hydrogen plasma) of hydrogen and the produced excited and decomposed gas (that is, the oxygen plasma) of oxygen passes over the wall face of the opening part 10A and the side face 10B in the film forming target member 10 held by the holding member 41 and is exhausted from the exhaust pipe 50. Then, the trimethyl gallium, which is present around the film forming target member 10, and the trimethyl gallium, which is adsorbed on the interior and the side face as well as on the surface of the film forming target member 10, are exposed to the produced excited and decomposed gas (that is, the hydrogen plasma) of hydrogen and the produced excited and decomposed gas (that is, the oxygen plasma) of oxygen.

Then, the trimethyl gallium is excited and decomposed by the excited and decomposed gas (that is, the hydrogen plasma) of hydrogen. Then, the excited and decomposed Ga reacts with the excited and decomposed gas (that is, the oxygen plasma) of oxygen, and a reaction product thereof deposits on the wall face of the opening part 10A and the side face 10B as well as on the surface of the film forming target member 10. As a result, the gallium oxide (GaO) film is formed as a film.

Additionally, for example, in a case where the Al film is formed as a film, the trimethyl aluminum serving as the film forming gas is excited and decomposed by the excited and decomposed gas (that is, the hydrogen plasma) of hydrogen serving as the film non-forming gas, and the produced Al deposits on the wall face of the opening part 10A and the side face 10B as well as on the surface of the film forming target member 10.

As described above, in the film forming apparatus 101 related to Exemplary Embodiment A, due to the exhaust pressure of the exhaust pipe 50, the excited and decomposed gases of the film forming gas and the film non-forming gas flow to and reach the opening part 10A and the side face 10B of the film forming target member 10.

For that reason, a substantially uniform film having the element contained in the film forming gas as the constituent element or a substantially uniform film having the element contained in the film forming gas and the element contained in the film non-forming gas as the constituent element are also formed on the wall face of the opening part 10A and the side face 10B in the film forming target member 10.

### Exemplary Embodiment B

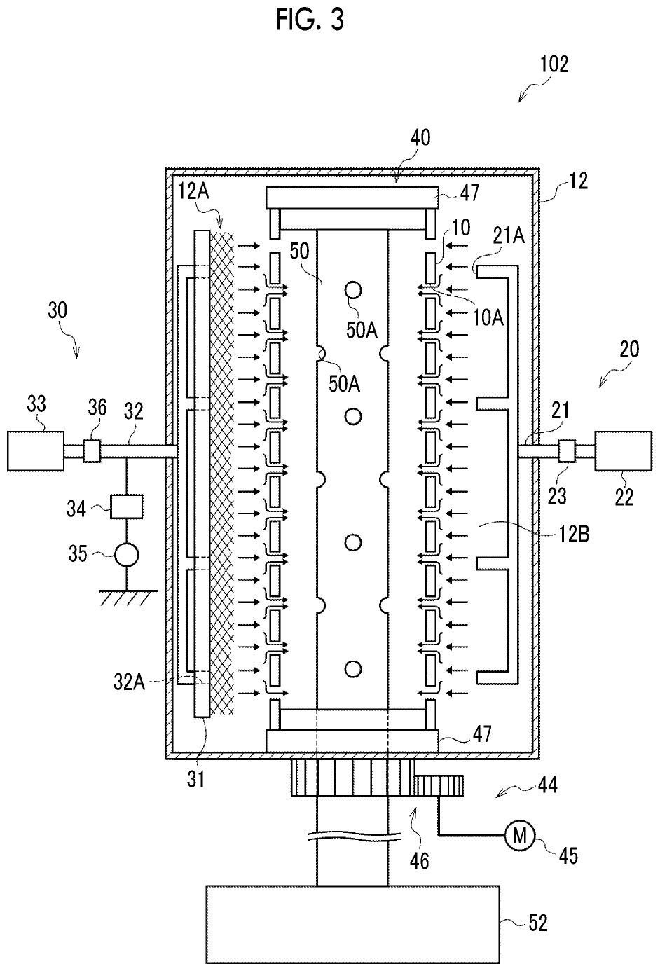

FIG. 3 is a schematic side cross-sectional view illustrating a film forming apparatus 102 related to Exemplary Embodiment B.

As illustrated in FIG. 3, the film forming apparatus 102 related to Exemplary Embodiment B is an apparatus that has the “tubular part 42 of the holding member 41” in the film forming apparatus 101 related to Exemplary Embodiment A as a tubular film forming target member 10.

Specifically, in the film forming apparatus 102, the holding member 41 has a pair of holding parts 47 that holds both end parts of the tubular film forming target member 10. One of the pair of holding parts 47 is coupled to the driving transmission part 46 of the drive unit 44.

The tubular film forming target member 10 has the opening part 10A through which the excited and decomposed gas of the film forming gas (and the film non-forming gas) permeates. Specifically, as the tubular film forming target member 10, a porous body, or a member having through-holes in a thickness direction thereof is adopted. In addition, an example in which the member having through-holes in the thickness direction is adopted as the tubular film forming target member 10 is illustrated in FIG. 3.

Since the film forming apparatus 102 related to Exemplary Embodiment B has the same configuration as the film forming apparatus 101 related to Exemplary Embodiment A except for the above configuration, the description thereof will be omitted.

As described above, even in the film forming apparatus 102 related to Exemplary Embodiment B, due to the exhaust pressure of the exhaust pipe 50 which is an example of an exhaust member, the excited and decomposed gases of the film forming gas and the film non-forming gas flow to and reach the opening part 10A of the tubular film forming target member 10.

For that reason, a substantially uniform film having the element contained in the film forming gas as the constituent element or a substantially uniform film having the element contained in the film forming gas and the element contained in the film non-forming gas as the constituent element are also formed on the wall face of the opening part 10A of the tubular film forming target member 10.

### Exemplary Embodiment C

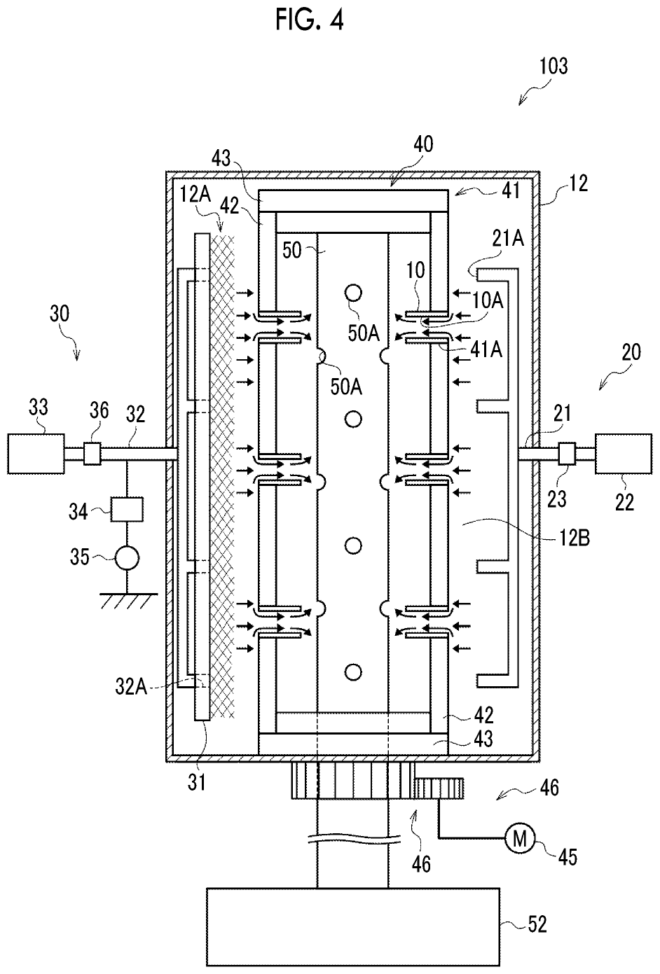

FIG. 4 is a schematic side cross-sectional view illustrating a film forming apparatus 103 related to Exemplary Embodiment C.

As illustrated in FIG. 4, the film forming apparatus 103 related to Exemplary Embodiment C is an apparatus in which the tubular part 42 having the opening part 41A holding the tubular film forming target member 10 is adopted as the “tubular part 42 of the holding member 41” in the film forming apparatus 101 related to Exemplary Embodiment A.

Specifically, in the film forming apparatus 103, the tubular part 42 of the holding member 41 holds the tubular film forming target member 10 by fitting the tubular film forming target member 10 into the opening part 10A.

A pipe, a belt, or the like is exemplified as the tubular film forming target member 10.

Since the film forming apparatus 103 related to Exemplary Embodiment C has the same configuration as the film forming apparatus 101 related to Exemplary Embodiment A except for the above configuration, the description thereof will be omitted.

As described above, even in the film forming apparatus 103 related to Exemplary Embodiment C, due to the exhaust pressure of the exhaust pipe 50 which is an example of an exhaust member, the excited and decomposed gases of the film forming gas and the film non-forming gas flow to and reach the inner peripheral face side of the tubular film forming target member 10.

For that reason, a substantially uniform film having the element contained in the film forming gas as the constituent element or a substantially uniform film having the element contained in the film forming gas and the element contained in the film non-forming gas as the constituent element are also formed on the inner peripheral face (that is, the wall face of the opening part 10A) of the tubular film forming target member 10.

### Exemplary Embodiment D

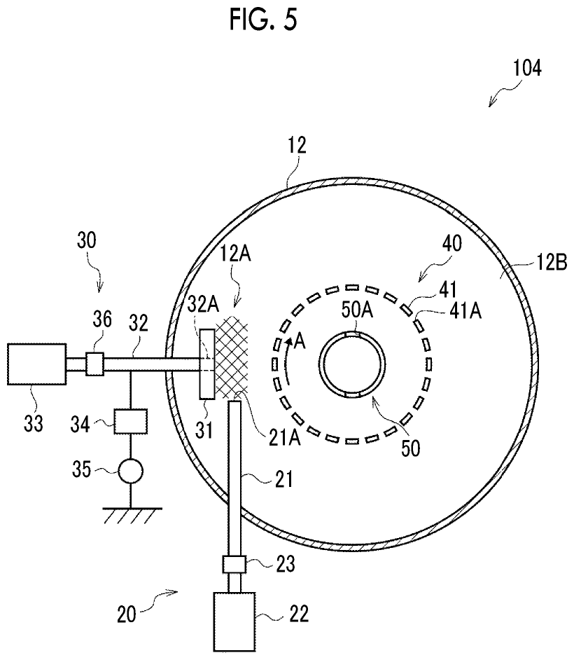

FIG. 5 is a schematic plan cross-sectional view illustrating a film forming apparatus 104 related to Exemplary Embodiment D.

As illustrated in FIG. 6, the film forming apparatus 104 related to Exemplary Embodiment D is an apparatus in which the film forming gas supply device 20 for supplying the film forming gas to the reaction active region within the reaction vessel 12 is adopted as the “film forming gas supply device 20” in the film forming apparatus 101 related to Exemplary Embodiment A.

Specifically, in the film forming apparatus 104, the film forming gas supply port 21A of the film forming gas supply device 20 is provided at the film forming gas supply pipe 21 in the reaction active region 12A within the reaction vessel 12.

Since the film forming apparatus 104 related to Exemplary Embodiment D has the same configuration as the film forming apparatus 101 related to Exemplary Embodiment A except for the above configuration, the description thereof will be omitted.

In the film forming apparatus 104 related to Exemplary Embodiment D, the film forming gas is directly supplied to the reaction active region 12A, not to the reaction inactive region 12B, and immediately excited and decomposed.

Even in such a film forming apparatus 104 related to Exemplary Embodiment I), due to the exhaust pressure of the exhaust pipe 50 which is an example of an exhaust member, the excited and decomposed gas of the film forming gas and the excited and decomposed gas of the film non-forming gas flow to and reach the opening part 10A and the side face 10B of the film forming target member 10.

For that reason, a substantially uniform film having the element contained in the film forming gas as the constituent element or a substantially uniform film having the element contained in the film forming gas and the element contained in the film non-forming gas as the constituent element are also formed on the wall face of the opening part 10A and the side face 10B in the film forming target member 10.

In addition, in any of the film forming apparatuses related to the exemplary embodiments, a heating device (not illustrated) for applying heat to the film forming target member 10 may be provided for the purpose of improving the crystallinity of a film to be formed, promoting a reaction for film formation, and the like. However, even in any of the film forming apparatuses related to the exemplary embodiments, it is realized that, in a state where heat is not applied to the film forming target member 10, a reaction product is produced and a film is formed.

Additionally, in any of the film forming apparatuses related to the exemplary embodiments, the composition of a film to be formed, the concentration of impurities, or the like is easily adjusted depending on the type of each of the film forming gas and the film non-forming gas, the combination of the film forming gas and the film non-forming gas, adjustment of the supply amount of the film forming gas and the film non-forming gas to be supplied into the reaction vessel 12 by controlling each of the electromagnetic valve 23 and the electromagnetic valve 36, or the type, the concentration, or the like of an impurity to be mixed with one or both of the film forming gas and film non-forming gas.

Additionally, the composition of the film to be formed on the film forming target member 10 is uniform with respect to the direction orthogonal to the film thickness, and may be uniform or may have variations with respect to the film thickness direction.

In a caps where the composition is changed in the film thickness direction, for example, the type of the film forming gas and the film non-forming gas, the supply amount of the film forming gas and the film non-forming gas, or the like may be changed whenever the holding member 41 is rotated at a targeted rotational speed.

As the film with nonuniform composition in the film thickness direction, specifically, there is a film obtained by laminating materials with different band gaps, such as a quantum well structure or a tandem type solar cell. Band gaps of nitride semiconductors of group 13 elements constituted of In, Ga, Al, and nitrogen are controlled by changing the concentration of the group 13 elements depending on mixed crystals in a range from InN (small band gap) to AIN (large band gap).

In this case, films having profiles in band gaps can be easily formed by changing the types and the supply amounts of gases containing the group 13 elements as the film forming gas or changing the mixing ratio of the gases in a case where the gases are mixed together.

Additionally, in order to control the physical properties of a film to be formed, an impurity may be added to a film as necessary. By mixing, for example, a gas containing an impurity element as the impurity with the above the film forming gas, a film containing the impurity is formed.

In a case where a film to be formed is a nitride semiconductor of a group 13 element, any of a donor impurity or an acceptor impurity may be added.

As the donor impurity, Li, Cu, Ag, Au, Mg, Zn, Si, Ge, Sn, Pb, S, Se, Te, or the like is exemplified. Among these, although there is no particular limitation, Si, Ge or Sn is preferable from a viewpoint of the controllability of an electric charge carrier.

As the acceptor impurity, Li, Na, Cu, Ag, Au, Be, Mg, Ca, Sr and Ba, Ra, Zn, Cd, Hg, C, Si, Ge, Sn, Pb, Cr, Fe, Co, Ni, or the like are exemplified. Among these, although there is no particular limitation, Be, Mg, Ca, Zn, or Sr is preferable from a viewpoint of the controllability of an electric charge carrier.

As film forming gases containing these impurity elements, SiH₄, GeH₄, GeF₄, or SnH₄ serving as the donor impurity or BeH₂, BeCl₂, BeCl₄, cyclopentadienyl magnesium, dimethyl calcium, dimethyl strontium, dimethyl zinc, diethyl zinc, or the like serving as the acceptor impurity can be supplied to the reaction inactive region. In a case where addition concentration is low, the supply amount is very small. Therefore, even in a case where film forming gases with these added impurities have film forming properties, a film forming gas may be introduced into the reaction active region, for example, by being diluted with a film non-forming gas.

Additionally, in any of the film forming apparatuses related to the exemplary embodiments, a form in which the excitation device 30 is provided with one discharge electrode 31 has been described. However, a plurality of discharge electrodes 31 may be provided. In this case, the film non-forming gas supply pipe 32, the film non-forming gas supply source 33, the matching box 34, the high-frequency power source 35, and the electromagnetic valve 36 may be provided for each discharge electrode 31. Additionally, the film non-forming gas supply source 33, the matching box 34, and the high-frequency power source 35 may be shared, may branch and supply electric power and gas.

Additionally, in any of the film forming apparatuses related to the exemplary embodiments, a form in which the film forming gas supply device 20 is provided with one film forming gas supply pipe 21 for supplying the film forming gas has been described. However, the film forming gas supply port 21A may be located in the reaction inactive region 12B, and a plurality of the film forming gas supply pipes 21 may be provided.

By providing the plurality of discharge electrodes 31 in this way, a plurality of the reaction active regions 12A and the reaction inactive regions 12B are provided within one reaction vessel 12. Moreover, in a case where the plurality of film forming gas supply pipes 21 are provided in the reaction vessel 12, the film forming gas is supplied to each of a plurality of the reaction inactive regions 12B. In this way, compared to a case where one discharge electrode 31 and one film forming gas supply pipe 21 are provided within one reaction vessel 12, the film forming speed increase, and a film forming apparatus with high film forming performance is obtained.

Additionally, in any of the film forming apparatuses related to the exemplary embodiments, a form in which the reaction active region 12A is a region where the excited and decomposed gas (that is, the film non-forming plasma) of the film non-forming gas in the reaction vessel 12 is reduced has been described. The reaction active region 12A may be a region where a reaction product having the element contained in the film forming gas as the constituent element can be produced from the film forming gas, and is not limited to a region where plasma is produced.

For example, the reaction active region 12A may be a region where the film forming gas is excited and decomposed by light or heat, or may be a region where the film forming gas is exposed to active species of the film non-forming gas in an excited state by light, an electron beam, a catalyst, or the like, and a chemical reaction or thermal decomposition is promoted.

In a case where the reaction active region 12A is formed by light, a light introduction port, which has a window allowing light of an excitation light source to be transmitted therethrough and is capable of being sealed in vacuum, may be used instead of the discharge electrode 31. Then, by guiding the light directed from a light source into a reactor through the light introduction port, the reaction active region 12A may be formed within the reaction vessel 12.

In this case, the film non-forming gas may not be supplied into the reaction vessel 12. As the excitation light source, a deuterium lamp, Xe lamp, a low-voltage mercury lamp, a high-voltage mercury lamp, an excimer lamp, or light sources including ultraviolet light or vacuum ultraviolet light of various laser light sources, such as nitrogen laser and an ArF laser, can be used.

Additionally, in a case where the reaction active region 12A is formed by a catalyst, a tungsten filament or the like that can be energized may be provided instead of the discharge electrode 31 so that the film non-forming gas passes over the surface of the tungsten filament of which the temperature has been raised by energization. Then, by spraying the film non-forming gas in an excited state toward the outer peripheral face of the holding member 41, the reaction active region may be formed within the reaction vessel 12.

In this case, the tungsten filament may be disposed in a compartment separate from the reaction vessel 12 via a mechanism, such as an orifice, which that may cause a pressure difference, and the interior of the compartment may be maintained at a pressure at which high excitation and decomposition efficiency resulting from the catalyst are obtained.

Additionally, in a case where the reaction active region 12A is formed by light, the reaction active region 12A may be heated by radiating light by a CO₂ laser or other infrared light sources with the same configuration as the method of guiding the ultraviolet light source into the reactor in the case where the reaction active region 12A is formed by light as shown above.

### EXAMPLES

Hereinafter, the invention will be more specifically described with reference to examples. However, the respective examples do not limit the invention.

### Example 1

An Al film was formed on a surface, a wall face of the opening part, and a side face, in a gear (maximum external diameter=10 mm, thickness=4 mm, and an example of the film forming target member 10) having an opening part at a central part thereof, using the film forming apparatus 101 illustrated in FIGS. 1 and 2.

In addition, main settings of the film forming apparatus are as follows.
Reaction vessel 12: a cylindrical member with an internal diameter of 400 mm and a cylindrical axial length of 400 mm. A material of an inner wall: stainless steel SUS304.
Tubular part 42 of holding member 41: a cylindrical stainless steel net with a diameter of 82 mm, an axial length of 340 mm, a sieve opening of 2 mm, and a porosity of 65%.
Size of discharge face of discharge electrode 31: a longitudinal length of 350 mm and a lateral length of 50 mm.
Film non-forming gas supply pipe 32: a copper pipe with an internal diameter of 1 mm.
Film non-forming gas supply port 32A: four ports are installed at intervals of 80 mm in the discharge face of the discharge electrode 31.
Film forming gas supply pipe 21: a stainless steel pipe with an internal diameter of 4 mm.
Film forming gas supply port 21A: four ports are installed at intervals of 80 mm.
Position of film forming gas supply port 21A: installed in the reaction inactive region 12B within the reaction vessel 12.
Spraying direction of film forming gas: a direction toward the outer peripheral face of the holding member 41.
Distance between discharge face of discharge electrode 31 and outer peripheral face of holding member 41: 35 mm.

Shielding members 24A and 24B: flat plate-shaped members (156 mm×400 mm, a thickness of 0.5 mm, and polyimide material).
Minimum distance between film forming target member 10 held by holding member and shielding members 24A and 24B (distance at the time of facing each other): 2 mm.
Attachment position of film forming target member 10: pasted using a Kapton adhesive tape (tradename) made TERAOKA SEISAKUSHO CO., LTD. on a total of 20 spots including five spots at intervals of 20 mm in the axial direction of the holding member 41 and four spots at regular intervals in the rotational direction on the outer peripheral face of the holding member 41 (the tubular part 42 thereof).

Using the film forming apparatus 101 of the above configuration, the interior of the reaction vessel 12 was evacuated via the exhaust pipe 50 until the pressure thereof was set to about 1×10⁻² Pa. Next, 500 sccm of hydrogen serving as the film non-forming gas was introduced from the film non-forming gas supply pipe 32 via the film non-forming gas supply port 32A provided in the discharge electrode 31 into the reaction vessel 12. Along with this, the conductance valve included in the evacuation device 52 was adjusted to set the pressure in the reaction vessel 12 20 Pa. Alternating current waves of 13.56 MHz output from the high-frequency power source 35 by the matching box 34 was set to an output of 100 W, matching was taken by a tuner, and discharge was performed from the discharge electrode 31. In this case, reflected waves are 0 W.

Next, trimethyl aluminum kept at 20° C. in a constant temperature bath was bubbled as the film forming gas as a hydrogen gas as a carrier gas, and was supplied from the film forming gas supply pipe 21 via the film forming gas supply port 21A to the reaction inactive region 128 within the reaction vessel 12 such that the flow rate of a mixed gas of the trimethyl aluminum and the hydrogen is 10 sccm. The conductance valve included in the evacuation device 52 was adjusted to set the pressure in the reaction vessel 12 to 20 Pa.

In this state, a film was formed for 90 minutes while the holding member 41 is rotated in the direction of arrow A at a rotating speed of 20 rpm. In this case, the temperature of the holding member 41 was in a range of about 25 to 50° C.

Through the above operation, the Al film with a thickness of 0.1 μm was formed on the surface, the wall face of the opening part, and the side face in the gear (maximum external diameter=10 mm, thickness=4 mm, and an example of the film forming target member 10) having the opening part at the central part thereof.

### Example 2

An α-Ga₂O₃ film was formed on a surface and wall faces of the through-holes in an aluminum tubular member (external diameter=82 mm, thickness=4 mm, diameter of through-holes=0.8 mm, number of through-holes=about 30000, and an example of the film forming target member 10) having through-holes, using the film forming apparatus 102 illustrated in FIG. 3.

In addition, main settings of the film forming apparatus are performed as follows. In addition, settings other than the following settings conform to those of Example 1.
Spraying direction of film forming gas: a direction toward the outer peripheral face of the film forming target member 10.
Distance between discharge face of discharge electrode 31 and outer peripheral face of film forming target member 10: 35 mm.

A film formation operation was carried out similarly to Example 1 using the film forming apparatus 102 of the above configuration except that the following points are changed.
Changed from trimethyl aluminum to trimethyl gallium.
Changed from 500 sccm of hydrogen to a mixed gas by joining 500 sccm of hydrogen and 5 sccm of He-diluted oxygen (oxygen 400) together.

Through the above operation, the α-Ga₂O₃ film with a thickness of 0.1 μm was formed on the surface and the wall faces of the through-holes in the aluminum tubular member having the through-holes.

### Example 3

An α-C film (DLC: diamond-like carbon) was formed on one end face and an inner peripheral face of a pipe (external diameter=2 mm, thickness=0.5 mm, length=5 mm, and an example of the film forming target member 10), using the film forming apparatus 103 illustrated in FIG. 4.

In addition, main settings of the film forming apparatus conform to those of Example 1.

A film formation operation was carried out similarly to Example 1 using the film forming apparatus 103 of the above configuration except that the following points are changed.
Changed from 10 sccm of trimethyl aluminum to 40 sccm of toluene.

Through the above operation, the α-C film (DLC:
diamond-like carbon) with a thickness of 0.15 μm was formed on the one end face and the inner peripheral face of the pipe.

### Comparative Examples 1 to 4

A modification in which an exhaust port is provided in an outer wall of the reaction vessel 12 and an exhaust pipe is coupled to the exhaust port was performed on each of the film forming apparatuses illustrated in FIGS. 1 to 4. Then, each film was formed on the same film formation conditions as Examples 1 to 4, using each apparatus. In addition, setting of each apparatus also conforms to settings of the apparatus of each example.

### EVALUATIONS

Film thickness of the films obtained in the respective examples was measured. Measurement spots are as follows.
Example 1 and Comparative Example 1: 1) the surface, 2) a reaction active region side (denoted as an “inner wall face front side” in Table) in the wall face of the opening part, 3) an opposite side (denoted as an “inner wall face back side” in Table) of the reaction active region in the wall face of the opening part, 4) a reaction active region side (denoted as a “side face front side” in Table) in the side face, and 5) an opposite side (denoted as a “side face back side” in Table) of the reaction active region in the side face, in each gear.
Example 2 and Comparative Example 2: 1) the surface, 2) a reaction active region side (denoted as an “inner wall face front side” in Table) in the wall face of the through-holes, 3) an opposite side (denoted as an “inner wall face back side” in Table) of the reaction active region in the wall faces of the through-holes, in each of the aluminum tubular members having the through-holes.
Example 3 and Comparative Example 3: 1) the one end face (denoted as a “surface” in Table), 2) a reaction active region side (denoted as an “inner wall face front side” in Table) in the inner peripheral face, 3) an opposite side (denoted as an “inner wall face back side” in Table) of the reaction active region in the inner peripheral face, in each of the pipes.

Hereinafter, details of the respective examples are shown as a list in Table 1.

TABLE 1

| | | | | Film Thickness (μm) | | | | |
|---|---|---|---|---|---|---|---|---|
| | | | | | Inner | Inner | Side | Side |
| | Film Forming | Film Forming | | | Wall Face | Wall Face | Face | Face |
| | Target Member | Apparatus | Film Type | Surface | Front side | Back Side | Front Side | Back Side |
| Example 1 | Gear | FIGS. 1 and 2: | Al Film | 1 | 0.92 | 0.88 | 0.92 | 0.90 |
| | | Exemplary | | | | | | |
| | | Embodimen tA | | | | | | |
| Example 2 | Tubular Member | FIG. 3: | α-Ga₂O₃ Film | 1 | 0.93 | 0.87 | — | — |
| | Having | Exemplary | | | | | | |
| | Through-Holes | Embodiment B | | | | | | |
| Example 3 | Pipe | FIG. 4: | α-C Film | 1 | 0.92 | 0.82 | — | — |
| | | Exemplary | | | | | | |
| | | Embodiment C | | | | | | |
| Comparative | Gear | Related-Art | Al Film | 1 | 0.96 | 0.10 | 0.95 | 0.15 |
| Example 1 | | Device | | | | | | |
| Comparative | Tubular Member | Related-Art | α-Ga₂O₃ Film | 1 | 0.96 | 0.12 | — | — |
| Example 2 | Having | Device | | | | | | |
| | Through-Holes | | | | | | | |
| Comparative | Pipe | Related-Art | α-C Film | 1 | 0.94 | 0.08 | — | — |
| Example 3 | | Device | | | | | | |

From the above results, in the present examples, it is understood that the formation of the substantially uniform film is realized on at least one of the interior or the side face of the film forming target member, compared to the comparative examples.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A film forming apparatus comprising:
a reaction vessel that has a film forming target member disposed therein and deposits a film having an element contained in a film forming gas as a constituent element on the film forming target member, utilizing excitation and decomposition of the film forming gas supplied thereto and that has a reaction active region where the film forming gas is capable of being excited and decomposed, and a reaction inactive region that is a region continuous with the reaction active region;
a film forming gas supply device that supplies the film forming gas to the reaction inactive region within the reaction vessel;
an excitation device that excites and decomposes the film forming gas in the reaction vessel;
a holding device that has a holding member which holds the film forming target member, and a drive unit which drives the holding member between the reaction inactive region and the reaction active region and repeatedly moves the film forming target member and which supplies the film forming gas from the reaction inactive region to the reaction active region together with the movement of the film forming target member; and
an exhaust member that is provided within the reaction vessel to exhaust a gas in the reaction vessel and that exhausts the gas in the reaction vessel that has passed through or over at least one of an interior or a side face of the film forming target member held by the holding member.

2. The film forming apparatus according to claim 1, further comprising:
a shielding member that is provided within the reaction vessel to shield at least a portion between the reaction active region and the reaction inactive region.

3. The film forming apparatus according to claim 1,
wherein the exhaust member is provided to face a film forming gas supply port of the film forming gas supply device via the film forming target member held by the holding member.

4. The film forming apparatus according to claim 1,
wherein the exhaust member is provided to face the reaction active region within the reaction vessel via the film forming target member held by the holding member.

5. The film forming apparatus according to claim 1,
wherein the holding member is a member that is provided to be interposed between a film forming gas supply port of the film forming gas supply device and the exhaust member and has an opening part through which the gas in the reaction vessel passes.

6. The film forming apparatus according to claim 1,
wherein the holding member is a member that is provided to be interposed between the reaction active region within the reaction vessel and the exhaust member and has an opening part through which the gas in the reaction vessel passes.

7. The film forming apparatus according to claim 5,
wherein the holding member is a tubular member.

8. The film forming apparatus according to claim 7,
wherein the exhaust member is provided on an inner peripheral face side of the tubular member serving as the holding member.

9. The film forming apparatus according to claim 1,
wherein the film forming target member is a member having an opening part through which the gas in the reaction vessel passes.

10. The film forming apparatus according to claim 9,
wherein the film forming target member is a porous body, a tubular member, or a member having through-holes in a thickness direction.

11. A film forming apparatus comprising:
a reaction vessel that has a film forming target member disposed therein and deposits a film having an element contained in a film forming gas as a constituent element on the film forming target member, utilizing excitation and decomposition of the film forming gas supplied thereto;
a film forming gas supply device that supplies the film forming gas to the reaction vessel;
an excitation device that excites and decomposes the film forming gas in the reaction vessel;
a holding member that is provided within the reaction vessel and holds the film forming target member; and
an exhaust member that is provided within the reaction vessel to exhaust a gas in the reaction vessel and that exhausts the gas in the reaction vessel that has passed through or over at least one of an interior or a side face of the film forming target member held by the holding member.

12. A film forming method comprising:
supplying a film forming gas to a reaction inactive region within a reaction vessel, the reaction vessel having a film forming target member disposed therein and deposits a film having an element contained in the film forming gas as a constituent element on the film forming target member, utilizing excitation and decomposition of the film forming gas supplied thereto and that has a reaction active region where the film forming gas is capable of being excited and decomposed, and the reaction inactive region that is a region continuous with the reaction active region;
exciting and decomposing the film forming gas in the reaction vessel;
driving a holding member between the reaction inactive region and the reaction active region in a state where the film forming target member is held by the holding member and moving the film forming target member repeatedly and supplying the film forming gas from the reaction inactive region to the reaction active region together with the movement of the film forming target member; and
exhausting a gas in the reaction vessel that has passed through or over at least one of an interior or a side face of the film forming target member held by the holding member.

13. The film forming method according to claim 12,
wherein at least a portion of a boundary between the reaction active region and the reaction inactive region within the reaction vessel is shielded with a shielding member.

14. The film forming method according to claim 12,
wherein the exhaust member is provided to face a film forming gas supply port of the film forming gas supply device via the film forming target member held by the holding member.

15. The film forming method according to claim 12,
wherein the exhaust member is provided to face the reaction active region within the reaction vessel via the film forming target member held by the holding member.

16. The film forming method according to claim 12,
wherein the holding member is a member that is provided to be interposed between a film forming gas supply port of the film forming gas supply device and the exhaust member and has an opening part through which the gas in the reaction vessel passes.

17. The film forming method according to claim 12,
wherein the holding member is a member that is provided to be interposed between the reaction active region within the reaction vessel and the exhaust member and has an opening part through which the gas in the reaction vessel passes.

18. The film forming method according to claim 16,
wherein the holding member is a tubular member.

19. The film forming method according to claim 18,
wherein the exhaust member is provided on an inner peripheral face side of the tubular member serving as the holding member.

20. The film forming method according to claim 12,
wherein the film forming target member is a member having an opening part through which the gas in the reaction vessel passes.

21. The film forming method according to claim 20,
wherein the film forming target member is a porous body, a tubular member, or a member having through-holes in a thickness direction.

22. A film forming method comprising:
supplying a film forming gas to a reaction vessel, the reaction vessel having a film forming target member disposed therein and deposits a film having an element contained in the film forming gas as a constituent element on the film forming target member, utilizing excitation and decomposition of the film forming gas supplied thereto;
exciting and decomposing the film forming gas in the reaction vessel; and
exhausting a gas in the reaction vessel that has passed through or over at least one of an interior or a side face of the film forming target member held by a holding member.
